(19) United States
(12) Patent Application Publication
(10) Pub. No.: US 2007/0269954 A1
(43) Pub. Date: Nov. 22, 2007

(54) Semiconductor device including a capacitor having reduced leakage current

(75) Inventors: Yoshitaka Nakamura, Tokyo (JP); Tomohiro Uno, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/802,052

(22) Filed: May 18, 2007

(30) Foreign Application Priority Data
May 19, 2006 (JP) 2006-140050

(51) Int. Cl. H01L 21/20

(52) U.S. Cl. 438/381

(57) ABSTRACT

A process for forming bottom and top electrodes of a capacitor uses a source gas including tungsten nitride carbide (WNC) which contains no chlorine, to form an amorphous electrode film. This prevents the amorphous capacitor insulation from being crystallized, and also prevents addition of chlorine into the capacitor insulation film, during a later heat treatment. Prevention of crystallization and addition of chlorine suppresses deterioration of the capacitor insulation film, to thereby reduce the leakage current across the capacitor insulation film.

This application is based upon and claims the benefit of priority from Japanese patent application No. 2006-140050 filed on May 19, 2006, the disclosure of which is incorporated herein in its entirety by reference.

### BACKGROUND OF THE INVENTION

1. Field of the Invention

The present invention relates to a semiconductor device and a method for manufacturing the same. In particular, the present invention relates to the structure of a semiconductor device preferably used for a semiconductor memory device and a method for manufacturing the same.

2. Description of the Related Art

A memory cell such as a DRAM (Dynamic Random Access Memory) cell is configured by a selection transistor and an associated storage capacitor. In the DRAM device, reduction in the amount of charge stored in the capacitor has become a major problem along with employment of a smaller design rule enabled by the development of the fine processing technology. In order to resolve the problem in the DRAM device, a COB (capacitor over bitline) structure and a STC (stacked trench capacitor) structure are adopted. The COB structure wherein the capacitor overlies the bit line allows the bottom area of the capacitor to be increased while avoiding interference. The STC structure wherein the capacitor has a cylindrical structure and thus has a larger depth allows the electrodes of the capacitor to have a larger opposing area therebetween. An example of the COB structure and STC structure is described in a literature, 2004 Symposium on VLSI Technology, Digest of Technical Papers, p 126 to 127.

The above literature describes a MIM (metal-insulator-metal) capacitor wherein the capacitor insulation film includes hafnium aluminum oxide (HfAlO) obtained by mixing hafnium oxide (HfO) and aluminum oxide (AlO), and the bottom and top electrodes are configured by a titanium nitride (TiN) film. In a conventional capacitor using a HfO film as the capacitor insulation film, there has been a problem that the leakage current across the capacitor significantly increases due to the heat treatment conducted at 500 to 550 degrees C. during and after forming the capacitor. In the above literature, HfAlO is used for the capacitor insulation film to resolve the problem of the increased leakage current.

As described in the above literature, the HfAlO used in the capacitor insulating film causes another problem that the storage capacitance per unit electrode area in the capacitor significantly reduces compared to the capacitor having the HfO film. This is due to the fact that the dielectric constant of AlO is around 9 whereas the dielectric constant of HfO is around 25. For example, the dielectric constant of HfAlO obtained by mixing HfO and AlO at a ratio of 1:1 is around 17, which is significantly low compared to the dielectric constant of HfO. If the capacitor insulation film has a thickness of 8 nm, for example, the equivalent oxide thickness (EOT) of the HfO film is 1.25 nm whereas the EOT of the HfAlO film is 1.84 nm. That is, the storage capacitance in the capacitor using the HfAlO film is reduced down to 68% of the storage capacitance in the capacitor using the HfO film.

The inventors found, as a result of a variety of tests, that the problem of the increased leakage current of the HfO film resulting from the heat treatment lies on the following facts. The first fact is that the titanium nitride (TiN) film used as the electrode has a higher crystallizing property, i.e., or is liable to crystallization. In order to obtain a lower leakage current across the capacitor insulation film, the crystallizing property of the capacitor insulation film should be lowered. In other words, the electrode should remain in an amorphous state. This is because if the electrode has a higher crystallizing property, the capacitor insulation film is also crystallized due to orientation to the crystallized electrode. In the HfO film, the crystal grain is grown by the heat treatment at around 550 degrees C., whereby the HfO film has irregularity in the thickness profile thereof. The resultant HfO film also has a crystal grain boundary within the film, which increases the leakage current across the film.

The second fact is that the CVD source gas contains chlorine. If the electrode contains therein chlorine, the chlorine reacts with the capacitor insulation film during the heat treatment at around 500 degrees C., which is conducted during the process for forming overlying interconnections after forming the capacitor. The chlorine reacted with the capacitor insulation degrades the characteristics of capacitor insulation film.

Patent Publication JP-2005-303306A describes a capacitor including a TiN electrode and a HfO₂ capacitor insulation film. In the capacitor described in this publication, in order to resolve the problem of the increased leakage current, a seed layer made of metal oxide is interposed between the bottom electrode and the capacitor insulation film, to prevent reaction between chlorine and the capacitor insulation film. This technique prevents crystallization of the capacitor insulation film. However, there is the disadvantage in this technique that the number of process steps increases due to the process for forming the seed layer. In addition, if the dielectric constant of the metal oxide in the seed layer is lower, the resultant capacitor has a lower capacitance to the extent of the lower dielectric constant that the capacitor insulation film has.

In the technique described in the literature as described before, a tungsten nitride (WN) film may be used for the electrode instead of the titanium nitride (TiN) film, to thereby resolve the problem that the capacitor insulation film includes chlorine due to the CVD source gas. However, the tungsten nitride film also has a higher crystallizing property, and hence the problem involved with the first fact remains unresolved, wherein the capacitor insulation film is crystallized to increase the leakage current across the capacitor insulation film.

### SUMMARY OF THE INVENTION

It is an object of the present invention to provide a semiconductor device including a capacitor having a lower leakage current substantially without a reduction in the storage capacitance of the capacitor, by suppressing crystallization of the capacitor insulation film and also deterioration of the capacitor insulation film by chlorine.

It is another object of the present invention to provide a method for manufacturing a semiconductor device having the capacitor as described above.

The present invention provides a semiconductor device including: a semiconductor substrate; and a capacitor including a bottom electrode, a capacitor insulation film and a top electrode consecutively formed to overlie the semiconductor substrate, wherein at least one of the bottom electrode and the top electrode is configured by a conductive film having an amorphous state.

The present invention also provides a method for manufacturing a semiconductor device including: forming an interlevel dielectric film receiving therein a cylindrical hole overlying a semiconductor substrate; forming a first conductive film on an inner sidewall of the cylindrical hole; processing the first conductive film to form a bottom electrode; forming a capacitor insulation film on the bottom electrode; forming a second conductive film on the capacitor insulation film: processing the second conductive film to form a top electrode, the bottom electrode, the capacitor insulation film and the top electrode configuring a capacitor; and forming an interconnection layer overlying the capacitor, wherein at least one of the first conductive film and the second conductive film has an amorphous state.

The above and other objects, features and advantages of the present invention will be more apparent from the following description, referring to the accompanying drawings.

### BRIEF DESCRIPTION OF THE DRAWINGS

FIG. 1 is a vertical sectional view showing a semiconductor memory device according to an embodiment of the present invention;

FIG. 2 is a vertical sectional view showing the detail of part of the semiconductor memory device of FIG. 1;

FIGS. 3 to 11 are vertical sectional views showing consecutive steps of a process for manufacturing a semiconductor memory device according to an embodiment of the present invention.

FIG. 12 is a vertical sectional view of a sample wafer used for a capacitor evaluation test;

FIG. 13 is a vertical sectional view of another sample wafer used for a capacitor evaluation test;

FIGS. 14A and 14B are graphs showing the I-V characteristic of the capacitor of the embodiment;

FIGS. 15A and 15B are graphs showing the I-V characteristic of the capacitor of a comparative example; and

FIG. 16 is a table showing the result of test for the samples and comparative examples.

### DETAILED DESCRIPTION OF PREFERRED EMBODIMENT

Now, an exemplary embodiment of the present invention will be described with reference to accompanying drawings, wherein similar constituent elements are designated by similar reference numerals.

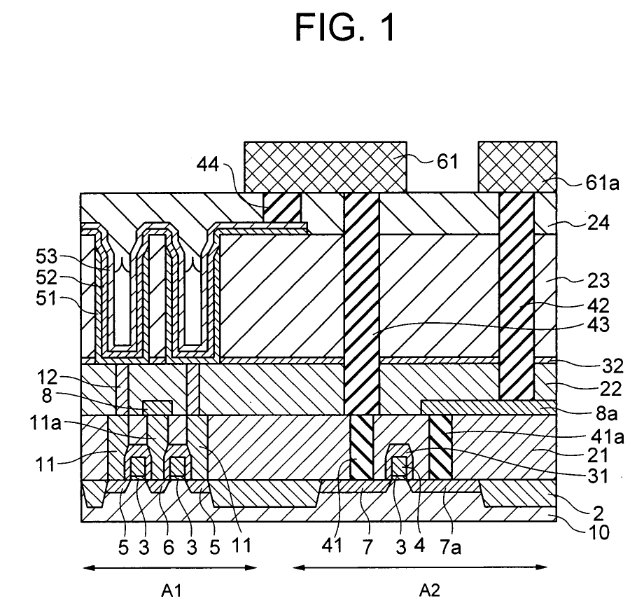

FIG. 1 is a vertical sectional view of a semiconductor memory device which is an example of the semiconductor device according to an embodiment of the present invention. In a memory cell area A1 shown in FIG. 1, active regions obtained by separating the main surface of the silicon substrate 10 by an isolation insulator film 2 receive therein two selection transistors each. Each of the selection transistors includes a gate electrode 4 formed on the main surface of the silicon substrate 10 with an intervention of a gate insulation film 3, and a pair of diffused regions 5 and 6 configured as source/drain regions. The diffused region 6 is shared by both the selection transistors.

For the selection transistors, a bit line 8 made from a tungsten film overlying interlayer dielectric films 21 and 31 is connected to the diffused region 6 via a polysilicon plug 11a passing through the interlayer dielectric film 21. The bit line 8 is covered by the interlayer dielectric film 22. A bottom electrode 51 made from a first tungsten nitride carbide film formed on the interlayer dielectric film 22, a capacitor insulation film 52 made from a hafnium oxide film having a thickness of 8 nm, and a top electrode 53 made from a second tungsten nitride carbide film having a thickness of 15 nm are stacked in this order to configure a capacitor.

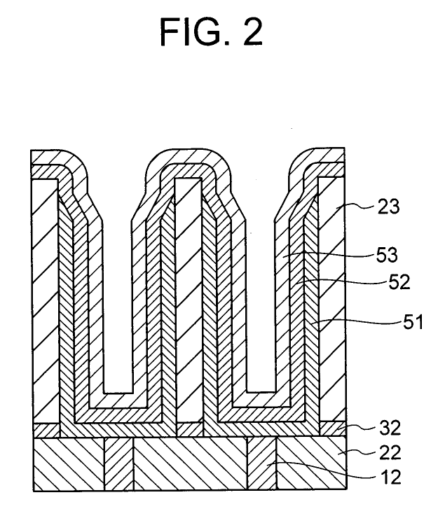

FIG. 2 shows an enlarged view of the vicinity of the capacitors shown in FIG. 1. In FIG. 2, the bottom electrode 51 is of a cylindrical shape having an open end and a closed bottom. The bottom surface of the bottom electrode 51 is connected to the top of the polysilicon plug 12. As shown in FIG. 1, the polysilicon plug 12 is electrically connected to the diffused region 5 of the selection transistor via a polysilicon plug 11 underlying the polysilicon plug 12, whereby the bottom electrode 51 is connected to the diffused region 5. The capacitor insulation film 52 covers the inner surface of the bottom electrode 51 and a portion of the interlevel dielectric film 23. The top electrode 53 is formed on the capacitor insulation film 52 to oppose the bottom electrode, with the capacitor insulation film 52 interposed therebetween.

Back to FIG. 1, a second layer interconnection 61 overlies the top electrode 53. The top electrode 53 and the second layer interconnection 61 are electrically connected through a via-plug 44 passing through an interlayer dielectric film 24. On the other hand, in a peripheral circuit area A2, transistors used for a periphery circuit are formed in the respective active regions obtained by isolating the main surface of the silicon substrate 10 by the isolation insulator film 2. The transistors each include a gate electrode 4 formed on the silicon substrate 10 with a gate insulation film 3 interposed therebetween, and a pair of diffused regions 7 and 7a formed in the surface region of the silicon substrate to configure source/drain regions. One diffused region 7 is electrically connected to the second layer interconnection 61 with metal plugs 41 and 43 interposed therebetween. The other diffused region 7a is electrically connected to a first layer interconnection 8a via a metal plug 41a. Further, the first layer interconnection 8a is electrically connected to a second layer interconnection 61a via a metal plug 42.

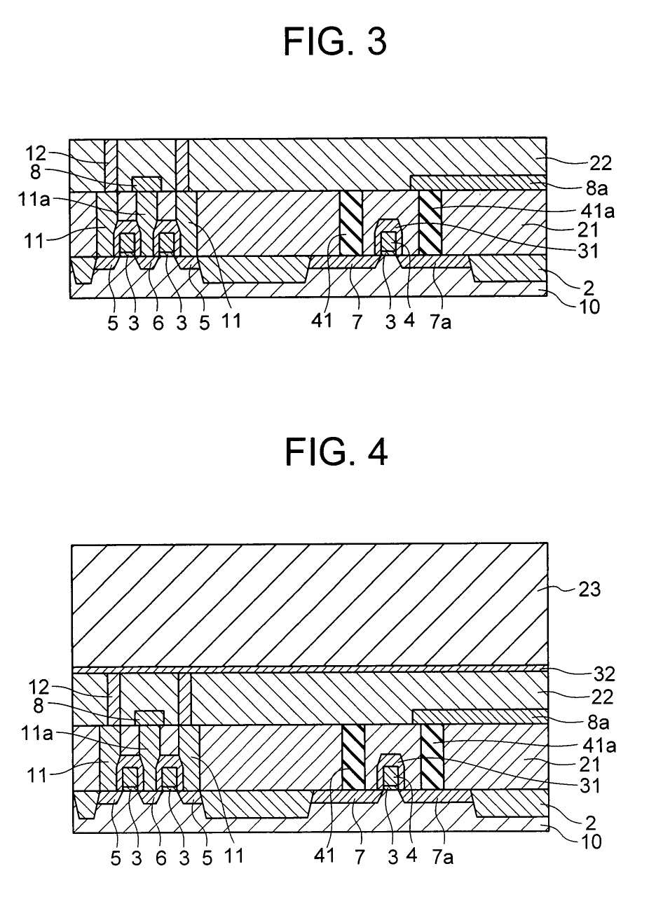

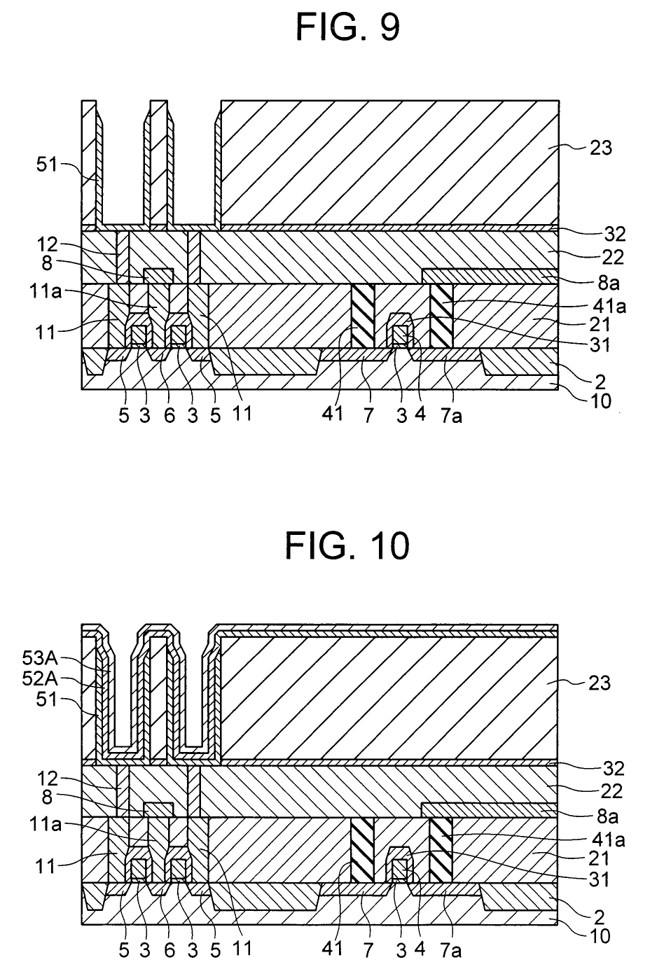

For describing the specific configuration of the semiconductor device of the present embodiment, a process for manufacturing the semiconductor memory will be described instead, with reference to FIGS. 3 to 11 as well as FIG. 1.

As shown in FIG. 3, the main surface of the silicon substrate 10 is divided by the isolation insulator film 2 to form a plurality of active regions. Thereafter, gate oxide film 3, gate electrodes 4, diffused regions 5, 6, 7, and 7a, polysilicon plugs 11, metal plugs 41 and 41a, bit lines 8 and first layer interconnections 8a are formed. Contact holes which pass through the interlayer dielectric film (silicon oxide film) 22 formed on the bit lines 8 and first layer interconnections 8a are filled with a polysilicon film, which is then etched back to leave the polysilicon plugs 12 in the contact holes. In this manner, the configuration shown in FIG. 3 is obtained.

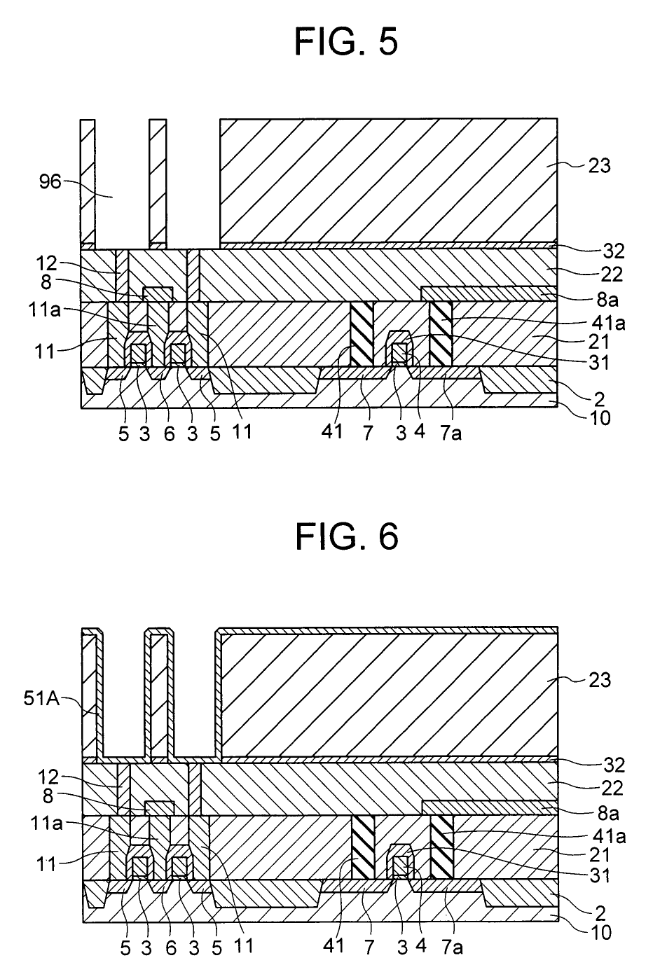

Thereafter, a silicon nitride film is formed as an interlayer dielectric film 32. On the interlayer dielectric film 32, a silicon oxide film having a thickness of 3 micrometers is formed as an interlayer dielectric film 23 to obtain the structure shown in FIG. 4. Subsequently, cylindrical holes 96 passing through the interlayer dielectric films 23 and 32 are formed using a photolithographic and dry etching technique. whereby the top of the polysilicon plugs 12 are exposed from the bottom surface of the cylindrical holes 96, as shown in FIG. 5.

Thereafter, a first tungsten nitride carbide film 51A having a thickness of 15 nm is grown on the entire surface as a bottom electrode layer, by using an atomic layer deposition (ALD) process, as shown in FIG. 6. The ALD process for the tungsten nitride carbide film 51A is performed using an in-line deposition system in which the wafer temperature is set at 300 degrees C. The Source gas used in the ALD process includes trimethylborane (B(CH₂CH₃)₃), tungsten hexafluoride (WF₆) and ammonia (NH₃).

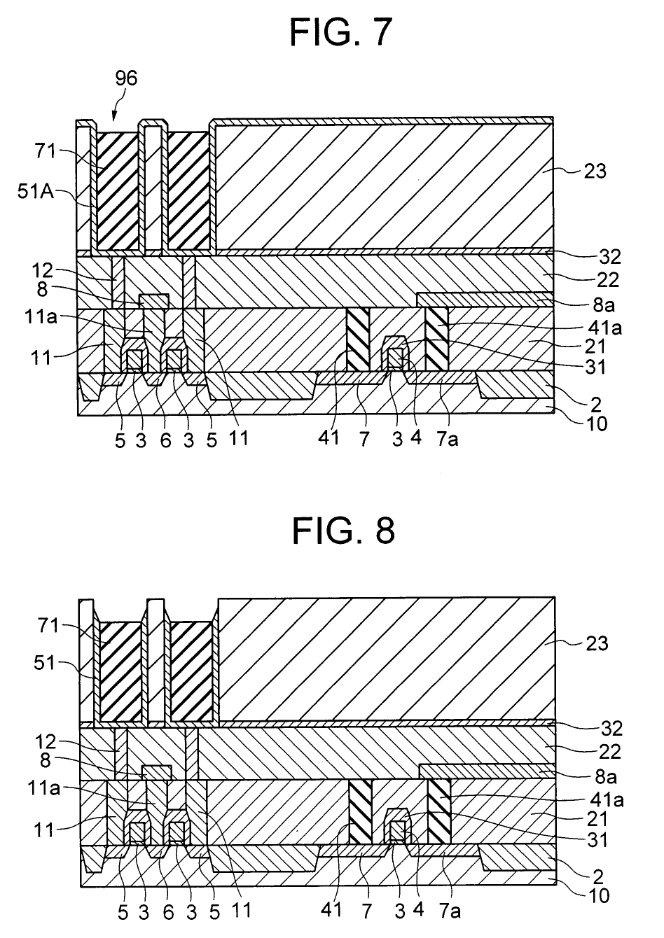

Thereafter, a photoresist film 71 is formed within the cylindrical holes 96, as shown in FIG. 7. While protecting a lower portion of the tungsten nitride carbide film 51A within the holes 96 against the etching, the upper portion of the tungsten nitride carbide film 51A is etched from the top portion of the cylindrical holes 96 and outside the cylindrical holes 96 by using an etch back technique, as shown in FIG. 8. Subsequently, an organic stripping liquid is used to remove the photoresist film 71 to expose bottom electrodes 51 having a cylindrical shape. Thereafter, a hafnium oxide film 52A having a thickness of 8 nm is formed using an ALD process. The ALD process for the hafnium oxide film 52A is performed using an in-line deposition system in which the wafer temperature is set at 350 degrees C. The Source gas in the ALD process includes tetrakis(ethylmethylamino)hafnium ([CH₃CH₂(CH₃)N]₄Hf) and ozone (O₃). Subsequently, a second tungsten nitride carbide film 53A having a thickness of 20 nm is formed as a top electrode layer by using an ALD process, to obtain the structure shown in FIG. 10. The ALD process for the tungsten nitride carbide film 53A uses, similarly to the ALD process for the first tungsten nitride carbide film 51A, an in-line deposition system in which the wafer temperature is set at 300 degrees C. The source gas in the ALD process includes trimethylborane, tungsten hexafluoride and ammonia.

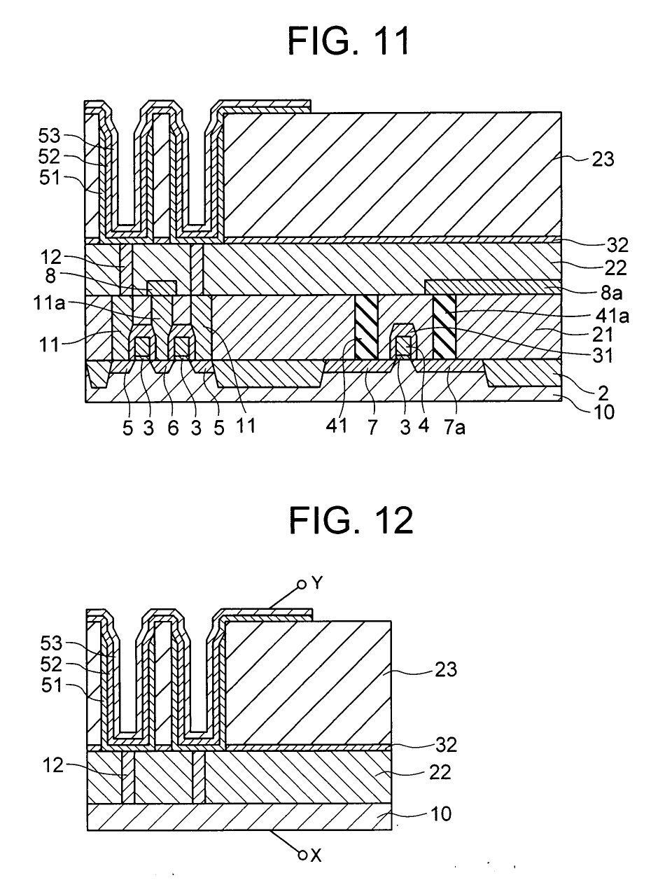

The second tungsten nitride carbide film 53A is selectively etched to have the pattern for the top electrode by using a photolithographic and dry etching technique, together with the hafnium oxide film 52A, to thereby obtain the structure of the capacitor insulation film 52 and top electrode 53. In this manner, the capacitor of a cylindrical shape having a depth of 3 micrometers is obtained, including the bottom electrode 51, capacitor insulation film 52, top electrode 53 as shown in FIG. 11.

Thereafter, as shown in FIG. 1, an interlayer dielectric film 24 made of silicon oxide is formed, followed by forming via-holes passing through the interlayer dielectric films 24, 23, 32 and 22. The via-holes are filled with a third titanium nitride film and a tungsten film, consecutively deposited. Subsequently, a portion of the third titanium nitride film and tungsten film outside the via-holes is removed by a CMP process, to thereby leave metal plugs 42, 43, and 44 in the via-holes. Subsequently, a titanium film, an aluminum film, and a titanium nitride film are consecutively deposited using a sputtering technique. These sputtered films are then patterned using a photolithographic and dry etching technique to obtain second layer interconnections 61 and 61a. In this manner, the structure shown in FIG. 1 is obtained.

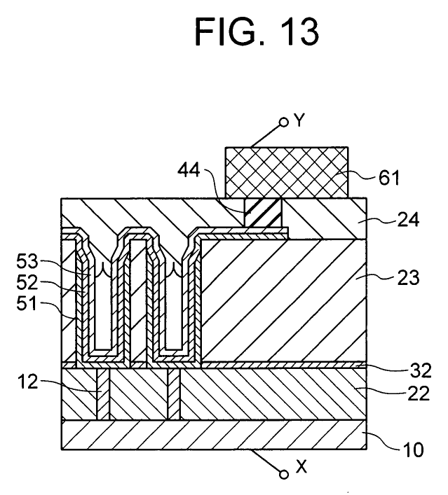

FIGS. 12 and 13 are vertical sectional views of first and second samples, respectively, of a semiconductor wafer manufactured by the process of the above embodiment, for the purpose of evaluating the characteristics of the capacitor. The first sample shown in FIG. 12 is different from the second sample shown in FIG. 13 in that the process for forming second sample includes the step of forming interlevel dielectric film 24 and overlying second layer interconnections 61. Both the samples were manufactured on the silicon substrate 10 in which arsenic (As) was doped at a concentration of 4e20/cm³.

The first sample shown in FIG. 12 includes polysilicon plugs 12, and a capacitor of WNC/HfO/WNC structure, that is, a MIM capacitor in which a tungsten nitride carbide (WNC) film is used for the bottom electrode 51 and top electrode 53, and a hafnium oxide (HfO) film is used for the capacitor insulation film 52, which were formed in accordance with the method of the above embodiment.

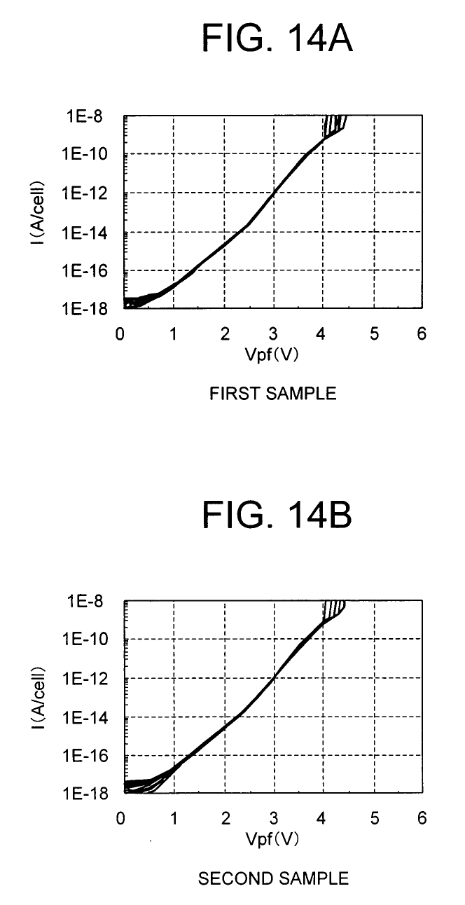

A TEG (test element group) in which 10-kilobit capacitors having the structure of FIG. 12 were connected in parallel was subjected to the current-voltage (I-V) characteristic test, with the potential of the silicon substrate (terminal X) being fixed at zero volt, and the potential of the top electrode (terminal Y) being varied from zero volt to +10 volts. During varying the potential at terminal Y, the current flowing from the terminal Y through the terminal X was measured to obtain the I-V characteristics of the capacitors. In FIG. 13, the second sample included a metal plug 44 and first layer interconnection 8a in addition to the structure of FIG. 12, and was also subjected to the similar I-V test. In the I-V test, the ambient temperature was set at 90 degrees C. FIGS. 14A and 14B show the test results for the first and second samples, respectively.

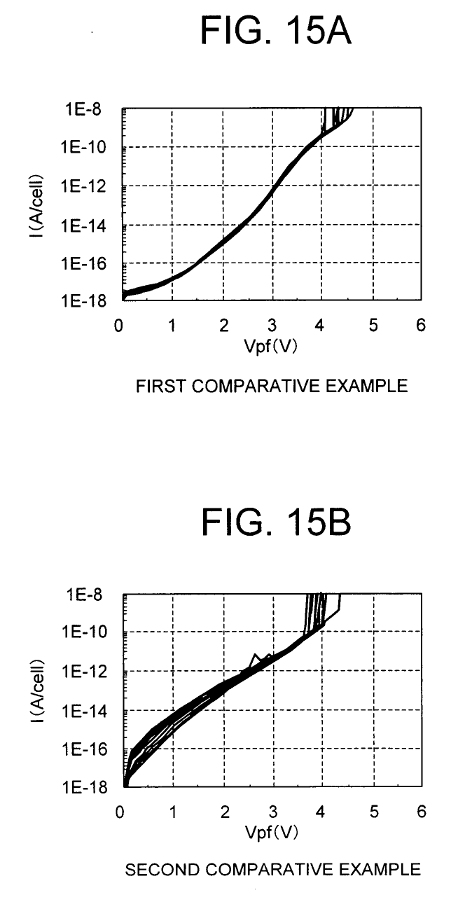

In addition, first and second comparative examples including a MIM capacitor of TiN/HfO/WNC structure were manufactured similarly to the first and second samples, respectively. The capacitor included tungsten nitride carbide film, titanium nitride (TiN) film and hafnium oxide film for the bottom electrode, top electrode and capacitor insulation film, respectively. The titanium nitride film was formed by a SFD (sequential flow deposition) process, which will be described later, using an in-line deposition system in which the wafer temperature was set at 500 degrees C. The source gas in the SFD process included titanium tetrachloride (TiCl₄) and ammonia (NH₃). The capacitor in the first and second comparative examples was similar that of the first and second samples except that the tungsten nitride carbide film of the top electrode in the samples was replaced by the titanium nitride film in the comparative example. The first and second comparative examples were tested similarly to the first and second samples, respectively. The results of the test is shown in FIGS. 15A and 15B similarly to FIGS. 14A and 14B, respectively.

As will be understood from FIGS. 14A and 14B, the capacitor in the samples revealed a lower leakage current, which is below 1E-16 A/cell at 1V, regardless of existence or absence of the overlying interconnections. On the other hand, the capacitor in the first comparative example without overlying interconnections revealed a lower leakage current in FIG. 15A, whereas the capacitor in the second comparative example having overlying interconnections revealed a higher leakage current in FIG. 15B. More specifically, the test result of the comparative examples revealed an increased leakage current after forming the overlying interconnections. Forming the metal plugs 42, 43, and 44 is accompanied by a heat treatment at least at 500 degrees C., and at 550 degrees C. or higher in a typical example, in the process for depositing the TiN film by using the CVD process. This process is considered to have deteriorated the capacitors in the second comparative example.

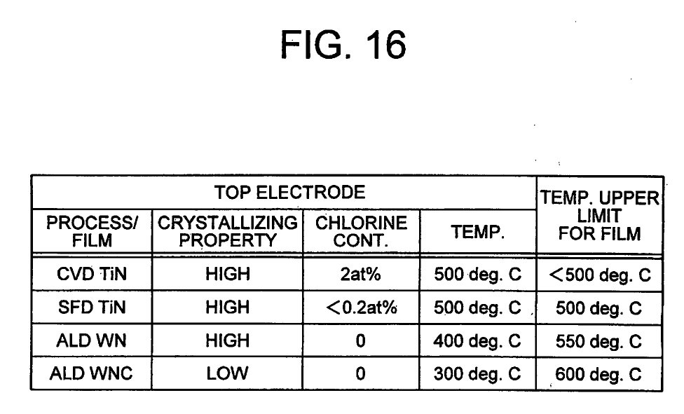

The experiment conducted by the inventors assured that the deterioration of the capacitor resulted partly from crystallization of the hafnium oxide film and partly from reaction of the hafnium oxide with chlorine. These results of the experiment are shown in a table in FIG. 16, with reference to which the results of the experiment and the cause of the defects will be described in detail hereinafter.

First, the leakage current of the capacitor in which the hafnium oxide film was used as the capacitor insulation film was maintained lower when the hafnium oxide film was in an amorphous state. For example, when the test voltage was 1V, the leakage current is lower than 1E-16 A/cell, as shown in FIG. 15A. However, the leakage current increased after the hafnium oxide film had been crystallized, as shown in FIG. 15B. This is considered because the crystal grain boundary formed by the crystallization of the hafnium oxide film formed a current path for passing therethrough a leakage current. Further, it was found that the crystallization of the hafnium oxide film depended on the heat treatment applied after the hafnium oxide film was formed, as well as on the crystallized state of the bottom electrode and the top electrode.

Thus, it is concluded that if a metal film having a higher crystallizing property, such as titanium nitride (TiN) film and tungsten nitride (WN) film, is used for the bottom electrode or the top electrode, the leakage current is increased by conducting a heat treatment at 550 degrees C. during or after forming the top electrode. However, if a metal film having a lower crystallizing property, such as a tungsten nitride carbide (WNC) film, is used for the top or bottom electrode, the leakage current is maintained lower even after a heat treatment at up to 600 degrees C. The reason is that if the bottom or top electrode has a higher crystallizing property, the capacitor insulation film is crystallized by orientation to the crystallized electrode.

Second, the leakage current of the capacitor in which hafnium oxide is used for the capacitor insulation film increases by a heat treatment conducted after the capacitor is formed, if a significant amount of chlorine (Cl) is contained in the electrode. If the titanium nitride film is used for the top electrode, the amount of chlorine contained in the titanium nitride film will be around 2 at % (atomic percents), assuming that the deposition temperature in the CVD process is 500 degrees C. and the CVD process is such that titanium tetrachloride (TiCl₄) and ammonia (NH₃) are concurrently supplied as a source gas.

On the other hand, if an ALD process in which tetrachloride titanium and ammonia are supplied alternately or a SFD which is modified from the ALD process is used, the amount of chlorine is maintained at 0.2 at % or lower. The SFD process is such that a first step in which tetrachloride titanium and ammonia are supplied alternately and a second step in which ammonia alone is supplied are repeated for a plurality of times.

If the titanium nitride film formed by the SFD process is used for the top electrode, the upper limit of temperature of the heat treatment at which the leakage current is maintained to a lower value was 550 degrees C. On the other hand, if the film is formed by the CVD process, the leakage current is increased by the heat treatment at 500 degrees C. (FIG. 15B). The reason is considered here that the barrier of the boundary surface between the electrode and the capacitor insulation film is lowered because the chlorine included in the top or bottom electrode reacts with the hafnium oxide to form hafnium chloride, and also the capacitor insulation film had an irregular thickness profile.

Although both the heat treatments were conducted at a wafer temperature of 500 degrees C. in both the process for forming the interconnections and the process for forming the top electrode, the capacitor insulation film was deteriorated only by the heat treatment in the process for forming the interconnections. The reason is now considered that there is an exhausting path through which the chlorine is exhausted from the electrode in the heat treatment in the process for forming the top electrode, whereas there is no such an exhausting path for the chlorine in the heat treatment in the process for forming the interconnections. The latter case may cause the capacitor insulation film to be baked in the chlorine gas, resulting in the high degree of deterioration in the capacitor insulation film.

It is noted here that the degree of deterioration of the capacitor insulation film is lower during forming the top electrode because the filming temperature for the tungsten nitride carbide film is lower than the filming temperature for the capacitor insulation film. This fact may also reduce the leakage current.

In the above embodiment, the hafnium oxide film is used as the capacitor insulation film. However, a zirconium oxide film or a tantalum oxide film may be used in place of the hafnium oxide film, for suppressing the increase of leakage current caused by crystallization and deterioration of the capacitor insulation film, if tungsten nitride carbide is used for the electrode.

In addition, in the above embodiment, tungsten nitride carbide is used for the top electrode or the bottom electrode. However, an electrode film of an amorphous state, such as made of titanium nitride carbide (TiNC), may be used instead, for suppressing the increase of the leakage current caused by crystallization of the capacitor insulation film.

Further, in the above embodiment, the MIM capacitor includes a metal film for both the top electrode and bottom electrode. However, a MIS (metal-insulator-semiconductor) capacitor including a polysilicon film for the bottom electrode may be used instead, for suppressing the increase of leakage current caused by crystallization and deterioration of the capacitor insulation film, if tungsten nitride carbide is used for the top electrode.

As described heretofore, the semiconductor device manufactured by the method of the above embodiment has the following advantages:

(1) suppression of crystallization and deterioration of the hafnium oxide film, which may otherwise result from a higher crystallizing property of the bottom electrode or the top electrode, a significant amount of chlorine contained in the bottom electrode or the top electrode, a heavier heat load on the capacitor insulation film during forming the top electrode, and so forth;
(2) suppression of the increase of leakage current of the capacitor, which may otherwise result from the crystallization and deterioration of the hafnium oxide film, due to the above advantage (1);
(3) improvement of reliability of the capacitor due to the above advantage (2); and
(4) improvement of reliability of the semiconductor device, especially of the semiconductor memory device (DRAM, etc.), due to the above advantage (3).

While the invention has been particularly shown and described with reference to exemplary embodiments thereof, the invention is not limited to these embodiments. It will be understood by those of ordinary skill in the art that various changes in form and details be made therein without departing from the spirit and scope of the present invention as defined in the claims.

For example, the present invention is not limited to a semiconductor memory device or method for forming a semiconductor memory device, and may be applied to any of the semiconductor devices including a capacitor.

What is claimed is:

1. A semiconductor device comprising:
a semiconductor substrate; and
a capacitor including a bottom electrode, a capacitor insulation film and a top electrode consecutively formed to overlie said semiconductor substrate,
wherein at least one of said bottom electrode and said top electrode is configured by a conductive film having an amorphous state.

2. The semiconductor device according to claim 1, wherein said conductive film includes tungsten titanium carbide or titanium nitride carbide.

3. The semiconductor device according to claim 1, wherein said conductive film contains chlorine at 0.2 atomic percent or lower.

4. The semiconductor device according to claim 1, wherein said capacitor insulation film is one selected from the group consisting of hafnium oxide film, zirconium oxide film and tantalum oxide film which have an amorphous state.

5. A method for manufacturing a semiconductor device comprising:
forming an interlevel dielectric film receiving therein a cylindrical hole overlying a semiconductor substrate;
forming a first conductive film on an inner sidewall of said cylindrical hole;
processing said first conductive film to form a bottom electrode;
forming a capacitor insulation film on said bottom electrode;
forming a second conductive film on said capacitor insulation film;
processing said second conductive film to form a top electrode, said bottom electrode, said capacitor insulation film and said top electrode configuring a capacitor; and
forming an interconnection layer overlying said capacitor,
wherein at least one of said first conductive film and said second conductive film has an amorphous state.

6. The method according to claim 5, wherein said at least one of said first conductive film and said second conductive film includes tungsten nitride carbide or titanium nitride carbide.

7. The method according to claim 5, wherein said capacitor insulation film is one selected from the group consisting of hafnium oxide film, zirconium oxide film and tantalum oxide film, which have an amorphous state.

8. The method according to claim 5, wherein said forming said first conductive film and/or said second conductive film uses a source gas containing no chlorine.

9. The method according to claim 5, wherein a wafer temperature used in said forming said second conductive film is lower than a wafer temperature used in said forming said capacitor insulation film.

10. The method according to claim 5, wherein said forming said first conductive film and/or said second conductive film uses an atomic layer deposition process or a sequential flow deposition process.

11. The method according to claim 5, wherein said forming said capacitor insulation film uses an atomic layer deposition process.

12. The method according to claim 5, wherein a wafer temperature used in a heat treatment in said processing said interconnection layer is lower than a wafer temperature used in said forming said second conductive film.

13. The method according to claim 12, wherein said wafer temperature used in said heat treatment in said processing said interconnection layer is 500 degrees C. or lower.
